(19) United States
(12) Patent Application Publication
(10) Pub. No.: US 2025/0008824 A1
(43) Pub. Date: Jan. 2, 2025

(54) LIGHT EMITTING DISPLAY DEVICE

(71) Applicant: LG Display Co., Ltd., Seoul (KR)

(72) Inventor: Jeong-Kyun SHIN, Paju-si (KR)

(73) Assignee: LG Display Co., Ltd., Seoul (KR)

(21) Appl. No.: 18/733,137

(22) Filed: Jun. 4, 2024

(30) Foreign Application Priority Data
Jun. 27, 2023 (KR) 10-2023-0082872

(51) Int. Cl. H10K 59/80; H10K 59/124; H10K 59/38

(52) U.S. Cl. CPC H10K 59/879; H10K 59/124; H10K 59/38; H10K 59/80518; H10K 59/877

(57) ABSTRACT

A light emitting display device according to one or more examples may include: a substrate; a driving element layer disposed on the substrate; a reflective electrode disposed on the driving element layer; a partition wall covering a circumference of the reflective electrode and exposing a middle portion of the reflective electrode; a planarization layer filling an inside area surrounded by the partition wall, and including a first refractive layer and a second refractive layer; an anode electrode disposed on the planarization layer; an emission layer disposed on the anode electrode; a cathode electrode disposed on the emission layer; and an encapsulation layer disposed on the cathode electrode.

### CROSS-REFERENCE TO RELATED APPLICATIONS

This application claims the benefit of and priority to the Korean Patent Application No. 10-2023-0082872 filed on Jun. 27, 2023 which is hereby incorporated by reference as if fully set forth herein.

### BACKGROUND

### Technical Field

The present disclosure relates to a display device and a pixel structure. Particularly, the present disclosure relates, for example, without limitation, to a light emitting display device and a pixel structure in which the light emitting efficiency is enhanced.

### Discussion of the Related Art

Recently, a head mount display (HMD) including an organic light emitting diode display has been developed. The HMD is a wearable monitor device, for example, for virtual reality (VR) or augmented reality (AR) that is worn in the form of glasses or a helmet so it focuses on a distance close to the user's eyes. Such a head-mounted display may be equipped with a small organic light emitting diode display with high resolution property. The head mount display may provide a virtual reality image to the user. Alternatively, the head mount display may include a liquid crystal display device, an inorganic light emitting display device, or the like.

Particularly, in an ultra-high density resolution display device having a pixel density of 4K (ppi: pixel per inch) or more, since the size of the pixel is very small, the structural improvement for improving light efficiency is required to provide a brighter and clearer image quality with the same power consumption.

The description of the related art should not be assumed to be prior art merely because it is mentioned in or associated with this section. The description of the related art may include information that describes one or more aspects of the subject technology, and the description in this section does not limit the invention.

### SUMMARY

The inventor of the present disclosure has recognized the problems and disadvantages of the related art and has performed extensive research and experiments. The inventor of the present disclosure has thus invented a new display device that substantially obviate one or more problems due to limitations and disadvantages of the related art.

In one or more aspects, a purpose of the present disclosure is to provide a top emission type light emitting display device or a top emission type transparent light emitting display device having high luminance compared to power consumption.

Some embodiments of the present disclosure may be directed to providing a top emission type light emitting display device or a top emission type transparent light emitting display device capable of low power driving with higher luminance with the same power consumption by including a color filter having a structure capable of improving light efficiency.

In order to accomplish one or more purposes of the present disclosure, a light emitting display device according to one or more example embodiments of the present disclosure may comprise: a substrate; a driving element layer disposed on the substrate; a reflective electrode disposed on the driving element layer; a partition wall covering a circumference of the reflective electrode and exposing a middle portion of the reflective electrode; a planarization layer filling an inside area surrounded by the partition wall, and including a first refractive layer and a second refractive layer; an anode electrode disposed on the planarization layer; an emission layer disposed on the anode electrode; a cathode electrode disposed on the emission layer; and an encapsulation layer disposed on the cathode electrode.

In an exemplary embodiment, an interface between the first refractive layer and the second refractive layer has a curved surface.

In an exemplary embodiment, the first refractive layer has a first refractive index. The second refractive layer has a second refractive index different from the first refractive index.

In an exemplary embodiment, the first refractive index is less than the second refractive index.

In an exemplary embodiment, a cross-sectional shape of the first refractive layer has a convex lens shape. A cross-sectional shape of the second refractive layer has a concave lens shape.

In an exemplary embodiment, an upper surface of the planarization layer is disposed on a same level as an upper surface of the partition wall.

In an exemplary embodiment, the planarization layer includes a plurality of silica nano particles.

In an exemplary embodiment, the planarization layer includes a plurality of quantum dots for implementing specific color.

In an exemplary embodiment, the light emitting display device further comprises: a color filter layer disposed on the encapsulation layer.

In an exemplary embodiment, the planarization layer includes a plurality of quantum dots implementing color corresponding to the color filter layer.

Furthermore, a light emitting display device according to one or more example embodiments of the present disclosure comprises: a substrate; a red pixel, a green pixel and a blue pixel; a driving element layer disposed on the substrate; a reflective electrode disposed at each of the red pixel, the green pixel and the blue pixel and disposed on the driving element layer; a partition wall covering circumferences of the reflective electrode and exposing middle portions of the reflective electrode; a planarization layer including a first refractive layer, a second refractive layer and a third refractive layer disposed within an area surrounded by the partition wall; an anode electrode disposed at each of the red pixel, the green pixel and the blue pixel and disposed on the planarization layer; a bank covering circumferences of the anode electrode and exposing middle portions of the anode electrode; an emission layer disposed on the anode electrode and the bank; and a cathode electrode disposed on the emission layer.

In an exemplary embodiment, a cross sectional shape of the first refractive layer has a convex lens shape in which a middle portion is convexed upward. A cross sectional shape of the second refractive layer has a concave lens shape in which a middle portion is concaved upward. A cross sectional shape of the third refractive layer has a convex lens shape in which a middle portion is convexed downward.

In an exemplary embodiment, the first refractive layer, the second refractive layer and the third refractive layer have refractive indices that are different from one another.

In an exemplary embodiment, the first refractive layer has a first refractive index that is less than a second refractive index of the second refractive layer. The second refractive layer has the second refractive index that is less than a third refractive index of the third refractive layer. The third refractive layer has the third refractive index that is less than a refractive index of the anode electrode.

In an exemplary embodiment, the light emitting display device further comprises: an encapsulation layer disposed on the cathode electrode; and a color filter layer including a red color filter at the red pixel, a green color filter at the green pixel, and a blue color filter at the blue pixel, where the color filter layer is disposed on the encapsulation layer.

In an exemplary embodiment, the planarization layer includes a plurality of silica nano particles.

In an exemplary embodiment, the planarization layer includes a plurality of first quantum dots at the red pixel, a plurality of second quantum dots at the green pixel, and a plurality of third quantum dots at the blue pixel.

In an exemplary embodiment, the planarization layer includes a red pigment at the red pixel, a green pigment at the green pixel, and a blue pigment at the blue pixel.

The light emitting display device according to one or more example embodiments of the present disclosure includes multi-layered refractive layers in the emission area, so that light extraction efficiency may be enhance or maximized. Even in an ultra-high density resolution display device having very small size of the emission area, higher luminance may be provided with the same power consumption. Accordingly, the low power driving may be implemented.

The light emitting display device according to one or more example embodiments of the present disclosure has a structural feature in which a plurality of refractive layers having different refractive indices from each other between the anode electrode and the reflective electrode. As a result, the light reflectance may be enhanced, and the light extraction efficiency may be improved.

The light emitting display device according to one or more example embodiments of the present disclosure has a structure in which an interface between the plurality of refractive layers having different refractive indices has a curved shape. The total reflectance at the interface may be remarkably reduced. Therefore, by reducing or minimizing the amount of light trapped inside the refractive layers by total reflection between the plurality of refractive layers, the light extraction efficiency may be further improved.

Other aspects, purposes, effects, devices, methods, features and advantages will be, or will become, apparent to one with skill in the art upon examination of the drawings and detailed description herein. It is intended that all such aspects, purposes, effects, devices, methods, features and advantages be included within this description, be within the scope of the present disclosure, and be protected by the following claims. Nothing in this section should be taken as a limitation on the claims. Further aspects and advantages are discussed below in conjunction with embodiments of the disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this application, illustrate aspects and embodiments of the disclosure, and together with the description serve to explain the principle of the disclosure.

FIG. 1 is a plane view illustrating a schematic structure of a light emitting display device according to an exemplary embodiment of the present disclosure.

FIG. 2 is a circuit diagram illustrating a structure of one pixel disposed in a light emitting display device according to an exemplary embodiment of the present disclosure.

FIG. 3 is an enlarged plan view illustrating a structure of three pixels sequentially disposed in the light emitting display device according to an exemplary embodiment of the present disclosure.

FIG. 4 is an example of a cross-sectional view along to cutting line I-I′ in FIG. 3, for illustrating a structure of one pixel in a light emitting display device according to a first exemplary embodiment of the present disclosure.

FIG. 5A is an example of a diagram illustrating a light path for a case in which a single transparent layer is disposed between the anode electrode and the reflective electrode.

FIG. 5B is an example of a diagram illustrating a light path for a case in which two layers having different refractive ratios each other are disposed between the anode electrode and the reflective electrode.

FIG. 6 is an example of an enlarged cross-sectional view, cutting along line II-II′ of FIG. 3, for illustrating a structure of three pixels sequentially arrayed in a light emitting display device according to a second exemplary embodiment of the present disclosure.

FIG. 7 is an example of an enlarged cross-sectional view, cutting along line II-II′ of FIG. 3, for illustrating a structure of three pixels sequentially arrayed in a light emitting display device according to a third exemplary embodiment of the present disclosure.

FIG. 8 is an example of an enlarged cross-sectional view, cutting along line II-II′ of FIG. 3, for illustrating a structure of three pixels sequentially arrayed in a light emitting display device according to a fourth exemplary embodiment of the present disclosure.

FIG. 9 is an example of an enlarged cross-sectional view, cutting along line II-II′ of FIG. 3, for illustrating a structure of three pixels sequentially arrayed in a light emitting display device according to a fifth exemplary embodiment of the present disclosure.

FIG. 10 is an example of an enlarged cross-sectional view, cutting along line II-II′ of FIG. 3, for illustrating a structure of three pixels sequentially arrayed in a light emitting display device according to a sixth exemplary embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these exemplary embodiments are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various exemplary embodiments of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the example embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

The word “exemplary” is used to mean serving as an example or illustration.

Embodiments are example embodiments. Aspects are example aspects. “Embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided. Any implementation described herein as an “example” is not necessarily to be construed as preferred or advantageous over other implementations.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

The terms, such as “below,” “lower,” “above,” “upper” and the like, may be used herein to describe a relationship between element(s) or item(s) as illustrated in the drawings. It will be understood that the terms are spatially relative and based on the orientation depicted in the drawings.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

Hereinafter, referring to the attached figures, the present disclosure will be explained. Since a scale of each of elements shown in the accompanying drawings may be different from an actual scale for convenience of description, the present disclosure is not limited to the scale shown in the drawings.

FIG. 1 is a plane view illustrating a schematic structure of a light emitting display device according to an exemplary embodiment of the present disclosure. In FIG. 1, X-axis refers to the direction parallel to the scan line, Y-axis refers to the direction parallel to the data line, and Z-axis refers to the height direction of the display device.

Referring to FIG. 1, the electroluminescence display comprises a substrate 110, a gate (or scan) driver 200, a pad portion 300, a source driving IC (Integrated Circuit) 410, a flexible circuit film 430, a circuit board 450, and a timing controller 500. However, embodiments of the present disclosure are not limited thereto.

As an example, the substrate 110 may include an electrical insulating material, a rigid material or a flexible material, without being limited thereto. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material. Embodiments are not limited thereto. As an example, the substrate 110 may include a semitransparent material or an opaque material.

The substrate 110 may include a display area AA and a non-display area NDA. The display area AA, which is an area for representing the video images, may be defined as the majority middle area of the substrate 110, but it is not limited thereto. In the display area AA, a plurality of pixels P are arrayed in a matrix manner. Further, a plurality of scan lines SL (or gate lines), a plurality of data lines DL may be disposed as crossing each other. Each of pixels P may be disposed at the crossing area of the scan line SL running to X-axis and the data line DL running to Y-axis.

Here, the pixel P may represent any one of color among red, green and blue or red, green, blue or white, without being limited thereto. Other colors such as cyan, magenta, yellow, etc. are also possible. A red pixel, a green pixel and a blue pixel may be gathered or a red pixel, a green pixel, a blue pixel and a white pixel may be gathered to form one unit pixel, without being limited thereto. For example, each of the pixels P representing each color may be called as a ‘sub-pixel’, and it may be explained that these ‘sub-pixels’ form one ‘pixel’. As another example, it may be explained that pixels P representing each color are called as ‘pixels’, and three or four of these ‘pixels’ are gathered to form one ‘unit pixel’. Hereinafter, the latter case will be described.

The non-display area NDA, which is an area not representing the video images, may be defined at the adjacent area or circumference areas of the substrate 110 surrounding all or some of the display area AA. In the non-display area NDA, the gate driver 200 and the pad portion 300 may be formed or disposed. Embodiments are not limited thereto. As an example, at least one of the gate driver 200 and the pad portion 300 may not be formed or disposed in the non-display area NDA.

The gate driver 200 may supply the scan (or gate) signals to the scan lines SL according to the gate control signal received from the timing controller 500 through the pad portion 300. The gate driver 200 may be formed at the non-display area NDA at any one or more side of the display area DA on the substrate 110, as a GIP (Gate driver In Panel) type. GIP type means that the gate driver 200 is directly formed on the substrate 110. For example, the gate driver 200 may be configured with shift registers. In the GIP type, the transistors for shift registers of the gate driver 200 are directly formed on the upper surface of the substrate 110. Embodiments are not limited thereto. As an example, the gate driver 200 may be separately provided (for example, on a separate panel), and then connected to the substrate 110 (e.g., the pad portion 300) in a tape automated bonding (TAB) method, a chip on glass (COG) method, a chip on panel (COP) method, or a chip on film (COF) method, without being limited thereto.

The pad portion 300 may be disposed in the non-display area NDA at one side edge of the display area AA of the substrate 110. The pad portion 300 may include data pads connected to each of the data lines DL, driving current pads connected to the driving current lines VDD, a high-potential pad receiving a high potential voltage, and a low-potential pad receiving a low potential voltage. One or more additional pad could be further included.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (Chip On Film) or COP (Chip On Plastic) type, without being limited thereto.

The flexible circuit film 430 may include a plurality of first link lines connecting the pad portion 300 to the source driving IC 410, a plurality of second link lines connecting the pad portion 300 to the circuit board 450, and/or a plurality of third link lines connecting the source driving IC 410 to the circuit board 450, without being limited thereto. The flexible circuit film 430 may be attached on the pad portion 300 using an anisotropic conducting film, so that the pad portion 300 may be connected to the first link lines or the second link lines of the flexible circuit film 430, without being limited thereto.

The circuit board 450 may be attached to the flexible circuit film 430. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be integrated with the source driving IC 410 into one driving chip and may be mounted on the substrate 110 to be connected to the pad unit 300.

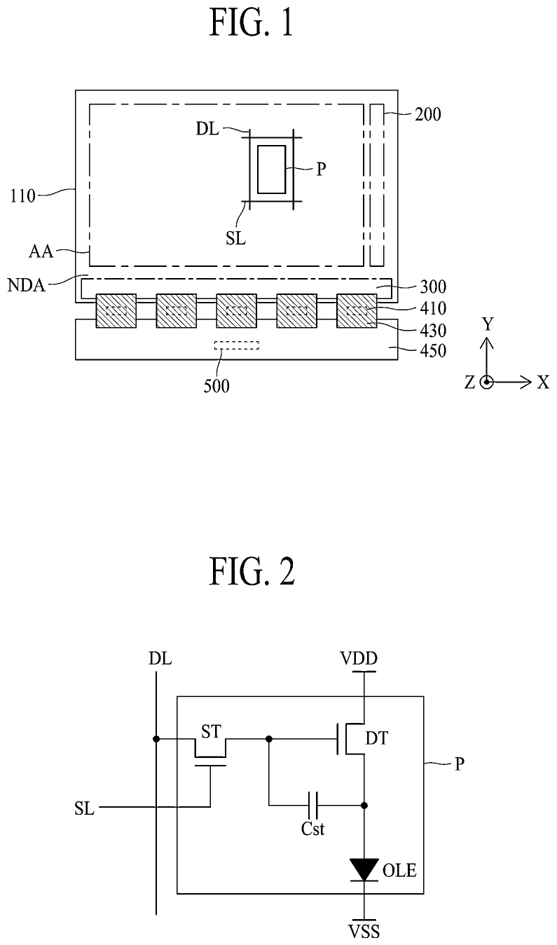

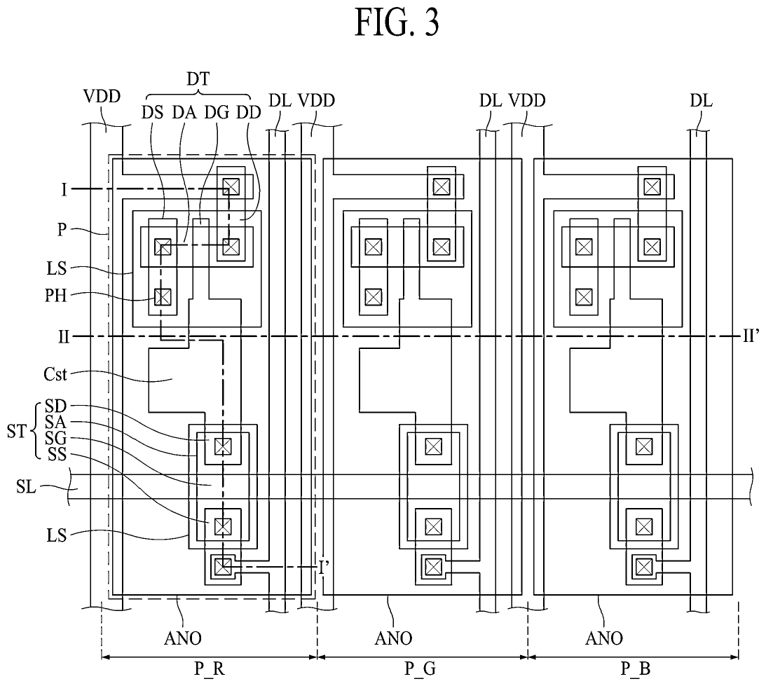

Hereinafter, referring to FIGS. 2 to 3, a detailed structure of a light emitting display device according to an exemplary embodiment of the present disclosure will be explained. FIG. 2 is a circuit diagram illustrating a structure of one pixel disposed in a light emitting display device according to an exemplary embodiment of the present disclosure. FIG. 3 is an enlarged plan view illustrating a structure of three pixels sequentially disposed in the light emitting display device according to an exemplary embodiment of the present disclosure.

Referring to FIGS. 2 to 3, each pixel P of the light emitting display according to the present disclosure may be defined by a scan line SL, a data line DL and a driving current line VDD. Each pixel P of the light emitting display may include a switching thin film transistor ST, a driving thin film transistor DT, a light emitting diode OLE and a storage capacitance Cst. The driving current line VDD may be supplied with a high-level voltage for driving the light emitting diode OLE. Embodiments are not limited thereto. At least one of the above-mentioned components could be omitted, and/or one or more additional components could be further included. As an example, more thin film transistors, storage capacitances and signal lines could be included in each pixel.

A switching thin film transistor ST and a driving thin film transistor DT may be formed on a substrate 110. For example, the switching thin film transistor ST may be configured to be connected to the scan line SL and the data line DL is crossing. The switching thin film transistor ST may include a gate electrode SG, a semiconductor layer SA, a source electrode SS and a drain electrode SD. The gate electrode SG may be a portion of the scan line SL. The semiconductor layer SA may be disposed as crossing the gate electrode SG. The overlapped portion of the semiconductor layer SA with the gate electrode SG may be defined as the channel area. The source electrode SS may be branched from or connected to the data line DL, and the drain electrode SD may be connected to the driving thin film transistor DT. The source electrode SS may be one side of the semiconductor layer SA with respect to the channel area, and the drain electrode SD may be the other side of the semiconductor layer SA. By supplying the data signal to the driving thin film transistor DT, the switching thin film transistor ST may play a role of selecting a pixel P which would be driven and controlling a timing at which the data signal is applied to the storage capacitance Cst.

The driving thin film transistor DT may play a role of driving the light diode OLE of the selected pixel P by the switching thin film transistor ST and controlling a current flowing through the light emitting diode OLE in accordance with a voltage applied to the gate electrode SG to control a luminance of the light emitting diode OLE. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended form the drain electrode SD of the switching thin film transistor ST. In the driving thin film transistor DT, the drain electrode DD may be branched from or connected to the driving current line VDD, further, the source electrode DS may be connected to the anode electrode (or pixel electrode) ANO of the light emitting diode (or light emitting element) OLE. The semiconductor layer DA may be disposed as crossing over the gate electrode DG. In the semiconductor layer DA, the overlapped portion with the gate electrode DG may be defined as a channel area. The source electrode DS may be connected at one side of the semiconductor layer DA with respect to the channel area, and the drain electrode DD is connected to the other side of the semiconductor layer DA. A storage capacitance Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may control the amount of current flowing from the driving current line VDD to the light emitting diode OLE according to the voltage difference between the gate electrode DG and the source electrode DS.

The light emitting diode OLE may include an anode electrode ANO, an emission layer EL, and a cathode electrode CAT. The light emitting diode OLE may emit lights according to the current controlled by the driving thin film transistor DT. In other words, the light emitting diode OLE may provide an image by emitting light according to the current controlled by the driving thin film transistor DT. The anode electrode ANO of the light emitting diode OLE may be connected to the source electrode DS of the driving thin film transistor DT. The cathode electrode CAT (or, common electrode) may be a part of the low-power line VSS supplied with the low-potential voltage or may be branched from or connected to the low-power line VSS. Therefore, the light emitting diode OLE may be driven by the electric current flown from the driving current line VDD to the low power line VSS controlled by the driving thin film transistor DT.

A plurality of pixels P may be arrayed on the substrate 110. For example, along the horizontal direction, a red pixel P_R, a green pixel P_G and a blue pixel P_B may be sequentially arrayed and disposed. The combination of the red pixel P_R, the green pixel P_G and the blue pixel P_B may configure one pixel. In another case, the red pixel, the green pixel, the white pixel and the blue pixel may be sequentially arrayed along the horizontal direction, the vertical direction or any direction between the horizontal direction and the vertical direction. The red pixel, the green pixel, the white pixel and the blue pixel may form a unit pixel. Embodiments are not limited thereto. Pixels of other colors may be alternatively or additionally included. FIG. 3 shows that three pixels P are sequentially arrayed along the horizontal direction.

### First Exemplary Embodiment

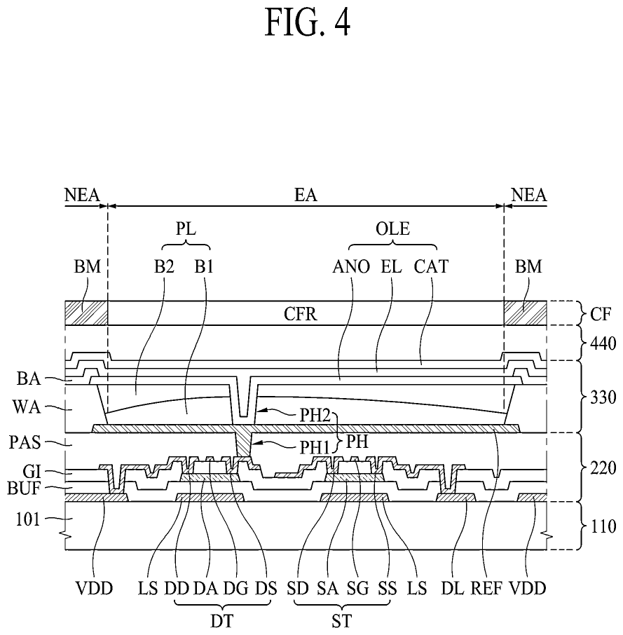

Further referring to FIG. 4, an example of a cross-sectional structure of the light emitting display device according to a first exemplary embodiment of the present disclosure will be explained. FIG. 4 is an example of a cross-sectional view along to cutting line I-I′ in FIG. 3, for illustrating a structure of one pixel in a light emitting display device according to a first exemplary embodiment of the present disclosure.

Referring to FIGS. 3 and 4, a light emitting display device according to the first exemplary embodiment of the present disclosure may include a substrate 110, a driving element layer 220, a light emitting element layer 330, an encapsulation layer 440 and a color filter layer CF, without being limited thereto. The driving element layer 220 may include a plurality of thin layers formed on the substrate 110. The driving element layer 220 may include a switching thin film transistor ST and a driving thin film transistor DT.

On the substrate 110, a data line DL, a driving current line VDD and a light shielding layer LS may be formed. The light shielding layer LS may be disposed in an island shape spaced apart from the data line DL and the driving current ling VDD by a predetermined distance and overlapping the semiconductor layers SA and DA, without being limited thereto. As an example, the light shielding layer LS may overlap at least one of the semiconductor layers SA and DA, or may be omitted according to the design. As an example, the light shielding layer LS may be floated or may be connected to a signal line. As an example, at least one of the data line DL, the driving current line VDD and the light shielding layer LS may be formed on a different layer.

A buffer layer BUF is deposited on the surface (e.g., the partial surface or the entire surface) of the substrate 110 as covering the data line DL and the driving current line VDD. On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. It is preferable that the channel areas in the semiconductor layers SA and DA at least partially overlap with the light shielding layer LS. Embodiments are not limited thereto. As an example, the semiconductor layer SA of the switching thin film transistor ST and the semiconductor layer DA of the driving thin film transistor DT may be formed on different layers.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG and the source-drain electrodes SS-SD and DS-DD are formed on the same layer, but are spatially and electrically separated from each other, without being limited thereto. As an example, at least one of the gate electrodes SG and DG and the source-drain electrodes SS-SD and DS-DD may be formed on a different layer. The source electrode SS of the switching thin film transistor ST may be connected to the data line DL via a contact hole penetrating the gate insulating layer GI. Further, the drain electrode DD of the driving thin film transistor DT may be connected to the driving current line VDD via another contact hole penetrating the gate insulating layer GI.

A passivation layer PAS is deposited on the substrate 110 as covering the thin film transistors ST and DT. The passivation layer PAS may be made of an inorganic material such as silicon oxide or silicon nitride, without being limited thereto. Further, the passivation layer 114 may be omitted depending on the exemplary embodiment.

The light emitting element layer 330 is formed on the driving element layer 220. The light emitting element layer 330 may include a reflective electrode REF, a partition wall WA, a planarization layer PL, a bank BA and a light emitting diode OLE. A reflective electrode REF having a size corresponding to each pixel P is formed on the passivation layer PAS. As an example, the reflective electrode REF may have a size corresponding to the light emitting diode OLE. As an example, the reflective electrode REF may have a size greater than, equal to or smaller than that of the light emitting diode OLE. As an example, the reflective electrode REF may have a size equal to or smaller than each pixel P. As an example, the reflective electrode REF may partially or entirely overlap the light emitting diode OLE. The reflective electrode REF may include a material (e.g., a metal material) having excellent light reflectance. For example, the reflective electrode REF may be formed of aluminum (Al), magnesium (Mg), calcium (Ca), silver (Ag) or alloy thereof (i.e., aluminum-magnesium (Al/Mg)), without being limited thereto.

The partition wall WA may be formed on the reflective electrode REF. The partition wall WA may be preferably formed of an inorganic material or an organic material. In this embodiment, the partition wall WA is formed of an organic material. The partition wall WA may cover circumference area of the reflective electrode REF, and expose most central area of the reflective electrode REF. The central area of the reflective electrode REF not covered by the partition wall WA may be defined as an emission area EA. The covered area of the partition wall WA may be defined as a non-emission area NEA.

The planarization layer PL is filled in the inner area of the emission area EA between the partition wall WA. The upper surface of the planarization layer PL may preferably form the same plane with the upper surface of the partition wall WA. As an example, the planarization layer PL may have a structure in which at least two refractive layers are stacked. For an example, as shown in FIG. 4, the planarization layer PL may have a structure in which a first refractive layer B1 and a second refractive layer B2 are sequentially stacked. Embodiments are not limited thereto. As an example, the planarization layer PL may have a structure of a single layer or more than two layers, without being limited thereto.

In detail, the first refractive layer B1 may be formed on the exposed are, (e.g., the central area) of the reflection electrode REF. The first refractive layer B1 may have a convex lens shape in which the bottom surface is flat but the middle portion of the upper surface is convex upward. The second refractive layer B2 may be stacked on the first refractive layer B1. The second refractive layer B2 has a flat upper surface. The lower surface of the second refractive layer B2 is in surface contact with the first refractive layer B1. Therefore, the second refractive layer B2 may have a concave lens shape with a concaved middle portion of the bottom surface. However, the arrangements of the first and second refractive layer B1 and B2 of the present disclosure are not limited thereto.

The cross-sectional shape (or profile) of the first refractive layer B1 may have a convex lens shape. In detail, in the cross section of the first refractive layer B1, the bottom surface has a straight plane profile, and the upper surface has a curved profile with the central portion being convex. The cross-sectional shape of the second refractive layer B2 may have a concave lens shape. In detail, in the cross section of the second refractive layer B2, the upper surface has a straight plane profile, and the lower surface has a curved profile with a concave central portion.

The first refractive layer B1 and the second refractive layer B2 may be formed of different materials (e.g., organic materials) from each other. For example, the first refractive layer B1 may be formed of a transparent organic material having a first refractive index. Further, the second refractive layer B2 may be formed of a transparent organic material having a second refractive index different from the first refractive index. The first refractive index may be higher or lower than the second refractive index. In this embodiment, the first refractive index may be lower than the second refractive index.

A pixel contact hole PH exposing a part of the source electrode DS of the driving thin film transistor DT is formed in the passivation layer PAS and the planarization layer PL. An anode electrode ANO may be formed on the upper surface of the partition wall WA and the planarization layer PL. As an example, the anode electrode ANO may be formed on the entire upper surface of the planarization layer PL. As an example, the anode electrode ANO may be formed on the entire upper surface of the planarization layer PL and a part of the upper surface of the partition wall WA. The anode electrode ANO may be connected to the source electrode DS of the driving thin film transistor DT via a pixel contact hole PH.

For example, as shown in FIG. 4, a first pixel contact hole PH1 may be formed at the passivation layer PAS. The reflective electrode REF formed on the passivation layer may be connected to the source electrode DS of the driving thin film transistor DT via the first pixel contact hole PH1. The reflective electrode REF may be covered by the planarization layer PL. A second pixel contact hole PH2 may be formed at the planarization layer PL. The anode electrode ANO formed on the planarization layer PL may be contacted to the reflective electrode REF via the second pixel contact hole PH2.

Even though it is not shown in figures, as an example, one pixel contact hole penetrating the passivation layer PAS, the planarization layer PL and the reflective electrode REF is formed to expose the source electrode DS of the driving thin film transistor DT. In this case, the anode electrode ANO formed on the planarization layer PL may be connected to the etched side surface of the reflective electrode REF and the upper surface of the source electrode DS of the driving thin film transistor DT via the pixel contact hole. Although it is illustrated that the anode electrode ANO is electrically connected to (e.g., contacted to) the reflective electrode REF, embodiments are not limited thereto. As an example, the anode electrode ANO may be not electrically connected to (e.g., not contacted to) the reflective electrode REF. As an example, the pixel contact hole PH may not penetrate the reflective electrode REF. As an example, the anode electrode ANO may be connected to the source electrode DS of the driving thin film transistor DT by bypassing the reflective electrode REF.

The anode electrode ANO may have different structure and configuring elements according to the emission type of the light emitting diode OLE. For example, in the case of a bottom emission type that provides lights in the direction of the substrate 110, it may be formed of a transparent conductive material. For another example, in the case of a top emission type that provides lights in the upward direction opposite the substrate 110, it may be formed of a conductive material having excellent light reflectance or any other conductive material. The light emitting display device according to the present disclosure is one of the top emission type. The anode electrode ANO may be formed of a transparent conductive material and the reflective electrode REF formed of a metal material having excellent reflectance may be disposed under the anode electrode ANO.

A bank BA is formed on the top surface of the substrate 110 having the anode electrode ANO. The bank BA is preferably an insulating layer made of an inorganic material or an organic material. Hereinafter, a case in which the bank is made of an in organic material will be described. The bank BA covers the circumferential areas of the anode electrode ANO, and exposes most of the central area of the anode electrode ANO. The central area of the anode electrode ANO exposed from the bank BA is defined as an emission area EA, and the area covered by bank BA is defined as a non-emission area NEA. As an example, the emission area EA defined by the bank BA may be correspond to the emission area EA defined by the partition wall WA. As an example, the emission area EA defined by the bank BA may be the same as the emission area EA defined by the partition wall WA. As an example, the emission area EA defined by the bank BA may have a size greater than, equal to or smaller than that of the emission area EA defined by the partition wall WA. As an example, the emission area EA defined by the bank BA may overlap the emission area EA defined by the partition wall WA. Embodiments are not limited thereto.

Therefore, in a plane view, the anode electrode ANO and the reflective electrode REF may have the same shape and size to be disposed as fully overlapped each other. In addition, it is preferable that the bank BA may have the same shape and size with the partition wall WA and may be disposed as fully overlapped with the partition wall WA. In other case, the reflective electrode REF may have a little larger size than the anode electrode ANO, so that the anode electrode ANO may be disposed within the area of the reflective electrode REF. As an example, the exposed area of the reflective electrode REF and the exposed area of the anode electrode ANO may have the same shape and size to be disposed as fully overlapped each other. As an example, the exposed area of the reflective electrode REF may be little larger than the exposed area of the anode electrode ANO.

An emission layer EL is disposed on the anode electrode ANO and bank BA. The emission layer EL may be deposited on entire of the display area AA of the substrate 110 as covering the anode electrode ANO and the bank BA. For an example, the emission layer EL may include at least two emission parts for generating white light. In detail, the emission layer EL may include a first emission part and a second emission part vertically stacked for generating white light by mixing the first light from the first emission part and the second light from the second emission part. Embodiments are not limited thereto. As an example, the emission layer EL may generate a light other than the white light. As an example, the emission layer EL may include one or more emission parts.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL, without being limited thereto.

A cathode electrode CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT may include a transparent conductive material. For example, the cathode electrode CAT may be made of a transparent conductive material such as indium-tin-oxide (ITO) or indium-zinc-oxide (IZO), without being limited thereto. Alternatively, the cathode electrode CAT may include a thin metal such as aluminum (Al), magnesium (Mg), calcium (Ca), silver (Ag) or an alloy or combination thereof (e.g., aluminum-magnesium alloy (AlMg)). It may be formed to have light-transmitting characteristics by forming it with a thin thickness less than 300A, without being limited thereto.

An encapsulation layer 440 is stacked on the light emitting element 220. The encapsulation layer 440 may have a single-layer structure made of an inorganic material, or a multi-layer structure in which several inorganic layers are sequentially stacked. As another example, the encapsulation layer 440 may have a structure in which an inorganic layer, an organic layer and an inorganic layer are continuously stacked. In FIG. 4, for convenience of description, the encapsulation layer 440 made of a single inorganic layer will be used for explanation. The encapsulation layer 440 can prevent the external moisture or oxygen from penetrating into the circuit elements (in particular, the light emitting element 220).

A color filter layer CF is stacked on the encapsulation layer 440. The color filter layer CF may be disposed in a structure in which one of a red color filter, a green color filter and a blue color filter is assigned to one pixel P. As another example, the color filter layer CF may be disposed in a structure in which one of a red color filter, a white color filter, a green color filter and a blue color filter is allocated to one pixel P. Hereinafter, for convenience of description, a case in which the color filter layer CF includes a red color filter CFR, a green color filter CFG and a blue color filter CFB is used for explanation. Embodiments are not limited thereto. As an example, a color filter for a different color may be alternatively or additionally included. As an example, the color filter layer CF may be omitted according to the design. As an example, a black matrix BM may be formed between adjacent color filters, or may be omitted according to the design.

The light emitting display device according to the first exemplary embodiment of the present disclosure has a structure in which a plurality of refractive layers are disposed between the anode electrode ANO and the reflective electrode REF. Specifically, each of the plurality of refractive layers may have different refractive index from each other and different cross-sectional shape from each other.

In detail, the first refractive layer B1 and the second refractive layer B2 may be disposed between the anode electrode ANO and the reflective electrode REF. The first refractive layer B1 may include an organic material having the first refractive index, and the cross-sectional shape of the first refractive layer B1 may be a convex lens shape. The second refractive layer B2 may include an organic material having the second refractive index, and the cross-sectional shape of the second refractive layer B2 may be a concave lens shape.

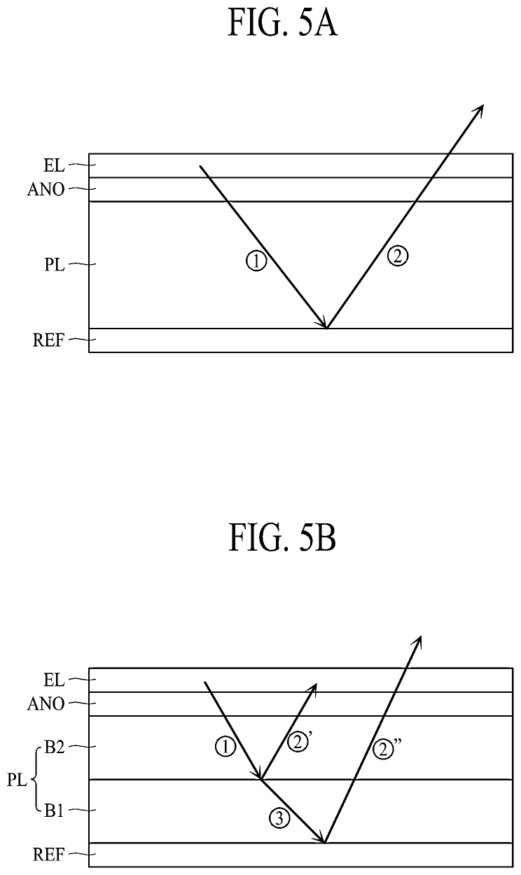

As shown in FIGS. 5A and 5B, the case in which two layers with different refractive indices are disposed shows different optical feature as compared to the case in which only one layer is disposed. FIG. 5A is an example of a diagram illustrating a light path for a case in which a single transparent layer is disposed between the anode electrode and the reflective electrode. FIG. 5B is an example of a diagram illustrating a light path for a case in which two layers having different refractive indexes from each other are disposed between the anode electrode and the reflective electrode.

Referring to FIG. 5A, an incident light \textcircled{1} going to the lower direction among the lights generated from the emission layer EL may enter into the planarization layer PL through the anode electrode ANO. The incident light \textcircled{1} passing through the planarization layer PL may be a reflected light \textcircled{2} by the reflective electrode REF, and may go back to the anode electrode ANO. Then, passing through the anode electrode ANO and the emission layer EL, the reflected light \textcircled{2} may go out of the display device. Here, when the light reflectance of the reflective electrode REF is 90%, the light amount of the reflected light \textcircled{2} may be 90% of the incident light \textcircled{1}, and 10% may be lost.

Referring to 5B, an incident light \textcircled{1} going to the lower direction among the lights generated from the emission layer EL may enter into the second refractive layer B2 of the planarization layer PL through the anode electrode ANO. Reflected at the interface between the second refractive layer B2 and the first refractive layer B1, some portions of the incident light \textcircled{1} may be a first reflected light \textcircled{2}′ so it may go back to the anode electrode ANO. Other portions of the incident light \textcircled{1} may be a refracted light \textcircled{3} so it may enter into the first refractive layer B1. Then, being reflected by the reflective electrode REF, the refracted light \textcircled{3} may be a second reflected light \textcircled{2}″ so it may go back to the anode electrode ANO.

Here, the light reflectance of the reflective electrode REF may be 90% and the light reflectance of the interface between the second refractive layer B2 and the first refractive layer B1 may be 30%. In this case, 30% of the incident light \textcircled{1} may be the first reflected light \textcircled{2}′ and the 70% of the incident light \textcircled{1} may be the refracted light \textcircled{3}. After that, as the 90% of the refracted light \textcircled{3} may be the second reflected light \textcircled{2}″, so the second reflected light \textcircled{2}″ may be 63% of the incident light \textcircled{1}. Therefore, the total reflected light may be 93% of the incident light \textcircled{1} that is the summation of the first reflected light \textcircled{2}′ and the second reflected light \textcircled{2}″. Here, in convenience, it is not considered that the second reflected light \textcircled{2}″ is refracted at the interface between the second refractive layer B1 and the first refractive layer B1.

With this way, when a plurality of refractive layers are stacked to form the planarization layer PL, the reflectance is higher than when the planarization layer PL includes a single layer, resulting in that the light extraction efficiency may be increased.

Furthermore, when the interface between the first refractive layer B1 and the second refractive layer B2 is plan surface, total reflection may be occurred at the interface. The total reflected light may be not go back to the anode electrode ANO, but is trapped inside the planarization layer PL so that it is eventually dissipated as thermal energy. However, as shown in FIG. 4, when the interface between the first refractive layer B1 and the second refractive layer B2 is curved surface, the probability of total reflection may be significantly decreased. Accordingly, the amount of light trapped inside the planarization layer PL by total reflection between the plurality of refractive layers may be minimized, and light extraction efficiency may be further improved.

### Second Exemplary Embodiment

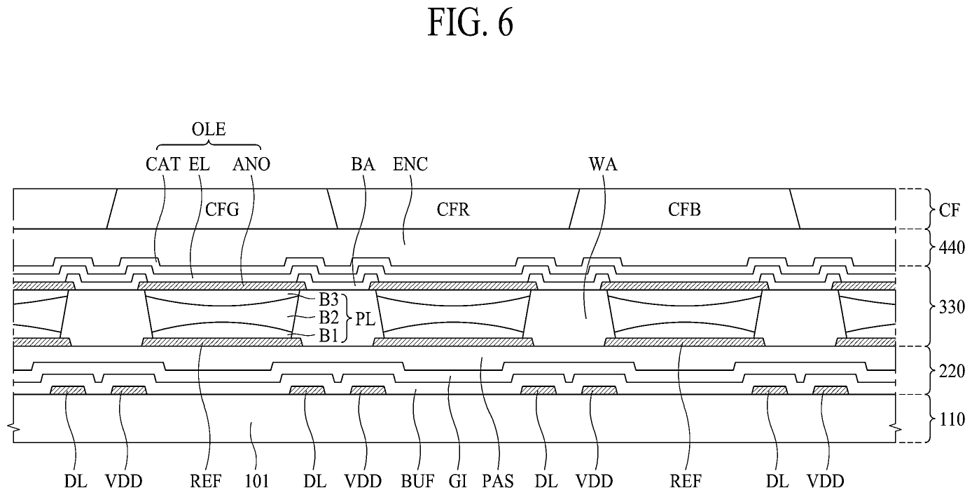

Hereinafter, referring to FIG. 6, a second exemplary embodiment of the present disclosure will be described. FIG. 6 is an example of an enlarged cross-sectional view, cutting along line II-II′ of FIG. 3, for illustrating a structure of three pixels sequentially arrayed in a light emitting display device according to a second exemplary embodiment of the present disclosure. In FIG. 6, the description for the elements below the driving element layer 220 is the same as those described in FIG. 4, so the same description will not be duplicated or be briefly given.

Referring to FIG. 6, the light emitting display device according to a second exemplary embodiment of the present disclosure may have similar structure with the first exemplary embodiment. In the second exemplary embodiment, the planarization layer PL may include three refractive layers being stacked.

In detail, the light emitting display device according to the second exemplary embodiment may comprise a substrate 110, a driving element layer 220, a light emitting layer 330, an encapsulation layer 440 and a color filter layer CF. The driving element layer 220 may include a plurality of film layers formed on the substrate 110. The driving element layer 220 may include a switching thin film transistor ST and a driving thin film transistor DT. As the structure of the driving element layer 220 may have same structure as the first exemplary embodiment, the same explanation may not be duplicated or be briefly given.

A reflective electrode REF having a size corresponding to each pixel P may be formed on the passivation layer PAS which is the topmost layer of the driving element layer 220. The reflective electrode REF may be formed as separately for each pixel P. The reflective electrode REF may include a metal material having excellent light reflectance.

A partition wall WA may be formed on the reflective electrode REF. The partition wall WA may be made of an organic material. The partition wall WA may cover circumferences of the reflective electrode REF and expose most of the central portions of the reflective electrode REF.

A planarization layer PL may be filled inside of the emission area EA between the partition wall WA. It is preferable that the top surface of the planarization layer PL may be same plane with the top surface of the partition wall WA. The planarization layer PL may include three refractive layers sequentially stacked.

In detail, a first refractive layer B1 may be formed on the central portions of the reflective electrode REF which is exposed by the partition wall WA. The bottom surface of the first refractive layer B1 has a plane surface, but the middle portion of the upper surface of the first refractive layer B1 may be curved surface of which middle portion is convexed upward. A second refractive layer B2 may be formed on the first refractive layer B1. The upper surface of the second refractive layer B2 may have a curved shape of which middle portion is concaved downward. The bottom surface of the second refractive layer B2 is contacted with the first refractive layer B1. Accordingly, the second refractive layer B2 may have a concaved lens shape of which middle portion is thinner than circumference portions. The top surface of the third refractive layer B3 has a plane surface. The bottom surface of the third refractive layer B3 is contacted with the second refractive layer B2. Accordingly, the third refractive layer B3 may have a convexed lens shape of which middle portion is convexed downward.

The cross-sectional shape (or, profile) of the first refractive layer B1 may have a convex lens shape. In the cross-sectional view of the first refractive layer B1, the bottom surface has straight plane surface, and the top surface has curved profile in which middle portion is convexed upward. The cross-sectional shape of the second refractive layer B2 may have a concave lens shape. In the cross-sectional view of the second refractive layer B2, the top surface has curved surface in which middle portion is concaved downward, and the bottom surface has curved profile in which middle portion is concaved upward. The cross-sectional shape of the third refractive layer B3 may have a convex lens shape. In the cross-sectional view of the third refractive layer B3, the top surface has straight plane surface, and the bottom surface has curved profile in which middle portion is convexed downward.

The first refractive layer B1, the second refractive layer B2 and the third refractive layer B3 may be made of different organic materials different each other, without being limited thereto. For an example, the first refractive layer B1 may be made of a first transparent organic material having a first refractive index. The second refractive layer B2 may be made of a second transparent organic material having a second refractive index different from the first refractive index. Further, the third refractive layer B3 may be made of a third transparent organic material having a third refractive index different from the first refractive index and the second refractive index. In an example, the first refractive index may be lower than the second refractive index, and the second refractive may be lower than the third refractive index without being limited thereto. Although it is illustrated that the planarization layer PL may include three refractive layers sequentially stacked, embodiments are not limited thereto. As an example, the planarization layer PL may include more than three refractive layers sequentially stacked. As an example, the more than three refractive layers may each have a convexed lens shape or a concaved lens shape. As an example, the more than three refractive layers may have different refractive indexes from each other. As an example, the more than three refractive layers may have refractive indexes gradually decreased from top to bottom, without being limited thereto.

A transparent anode electrode ANO may be disposed on the third refractive layer B3. The light emitting display device according to the present disclosure improves light extraction efficiency by causing light traveling downward from the emission layer EL to be reflected at the interface of the multilayer structure before being reflected from the reflective electrode REF. Therefore, it is preferable that the third refractive index of the third refractive layer B3 may be different from the refractive index of the anode electrode ANO, without being limited thereto. Particularly, the third refractive index may be lower than the refractive index of the anode electrode ANO.

A bank BA may be formed on the surface of the substrate 110 having the anode electrode ANO. The bank BA may be made of an inorganic material. As covering the circumferences of the anode electrode ANO, the bank BA may expose most middle portions of the anode electrode ANO. An emission layer EL may be formed on the anode electrode ANO and the bank BA. The emission layer EL may be deposited over all of the display area AA of the substrate as covering the anode electrode ANO and the bank BA.

A cathode electrode CAT may be deposited on the whole surface of the substrate 110 having the emission layer EL. The cathode electrode CAT may be stacked as being in surface contact with the emission layer EL. The cathode electrode CAT may be deposited across the entire surface of the substrate 110 to be commonly connected to the emission layer EL disposed in all pixels.

An encapsulation layer 440 is disposed on the light emitting element layer 220. The encapsulation layer 440 may have a single layered structure including an inorganic material, or an organic material, or a multi-layered structure in which a plurality inorganic layers and/or organic material are stacked sequentially. A color filter layer CF may be disposed on the encapsulation layer 440. The color filter layer CF may include a red color filter CFR, a green color filter CFG and a blue color filter CFB. As an example, the color filter layer CF may be omitted.

In the second exemplary embodiment of the present disclosure, three refractive layers B1, B2 and B3 having different refractive indices are stacked between the anode electrode ANO and the reflective electrode REF. Therefore, before the light emitted from the emission layer EL to the downward direction reaches to the reflective electrode REF, the light may be reflected at the interface between the anode electrode ANO and the third refractive layer B3, the interface between the third refractive layer B3 and the second refractive layer B2, and the interface between the second refractive layer B2 and the first refractive layer B1. Accordingly, the light extraction efficiency may be further improved compared to when the planarization layer PL is a single layer and compared to when the planarization layer PL include two refractive layers.

Since the interface between the third refractive layer B3 and the second refractive layer B2, and the interface between the second refractive layer B2 and the first refractive layer B1 have a curved shape, the probability of total reflection occurring may be reduced or minimized. Therefore, the light extraction efficiency may be further improved.

### Third Exemplary Embodiment

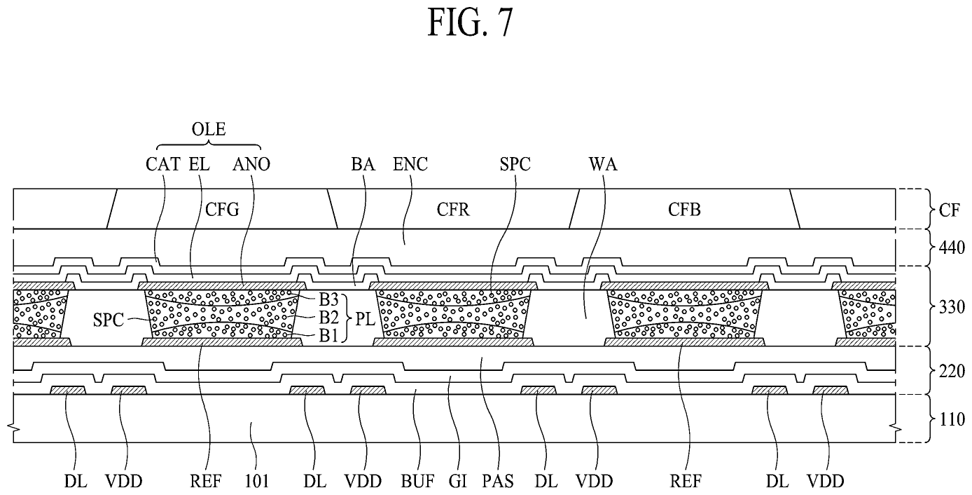

Referring to FIG. 7, a third exemplary embodiment of the present disclosure will be explained. FIG. 7 is an example of an enlarged cross-sectional view, cutting along line II-II′ of FIG. 3, for illustrating a structure of three pixels sequentially arrayed in a light emitting display device according to a third exemplary embodiment of the present disclosure. The light emitting display device according to the third exemplary embodiment shown in FIG. 7 may have a very similar structure with the second exemplary embodiment shown in FIG. 6. The explanation for same structure with the second exemplary embodiment may be not duplicated or may be briefly given.

In the third exemplary embodiment, a plurality of silica nano particles SPC may be included into the planarization layer PL. In an example, a plurality of silica nano particles SPC may be scattered in the first refractive layer B1, in the second refractive layer B2 and in the third refractive layer B3. In an example, the plurality of silica nano particles SPC may be dispersed into at least one of the first refractive layer B1, the second refractive layer B2 and the third refractive layer B3. It is preferable that the plurality of silica nano particles SPC may be dispersed into all the first refractive layer B1, the second refractive layer B2 and the third refractive layer B3.

The silica nano particles SPC may function to scatter light passing through the planarization layer PL. As a result, the light emitted from the emission layer EL to the lower direction and the light reflected from the reflective electrode REF to the upper direction are reduced or prevented from being trapped in the planarization layer PL during passing through the planarization layer PL, so that the scattering effect of the light may be increased. Accordingly, the light extraction effect may be further improved compared to the case where the silica nano particle SPC are not provided.

### Fourth Exemplary Embodiment

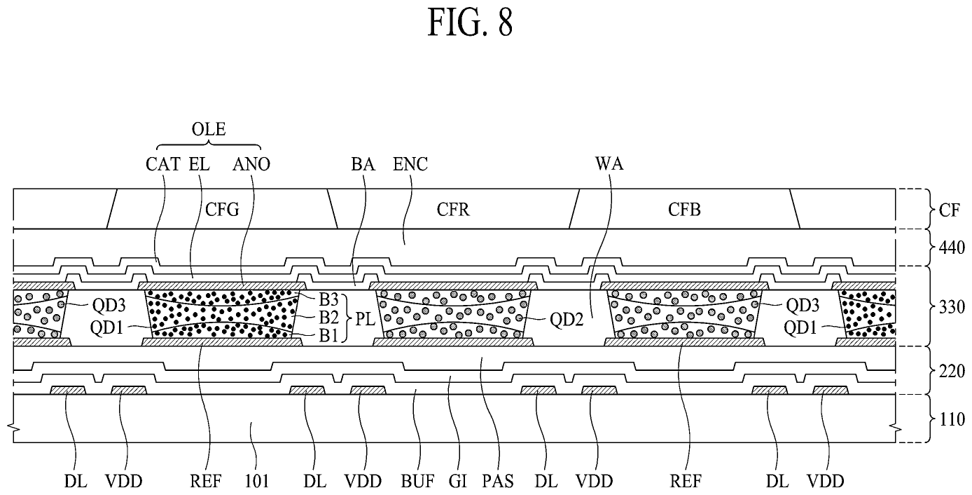

Hereinafter, referring to FIG. 8, a fourth exemplary embodiment of the present disclosure will be explained. FIG. 8 is an example of an enlarged cross-sectional view, cutting along line II-II′ of FIG. 3, for illustrating a structure of three pixels sequentially arrayed in a light emitting display device according to a fourth exemplary embodiment of the present disclosure. The light emitting display device according to the fourth exemplary embodiment shown in FIG. 8 may have a very similar structure with the second exemplary embodiment shown in FIG. 6. The explanation for same structure with the second exemplary embodiment may be not duplicated, or may be briefly given.

In the fourth exemplary embodiment, the planarization layer PL may include a plurality of quantum dots corresponding to the color allocated to each pixel P. The quantum dots may be dispersed into at least one of the first refractive layer B1, the second refractive layer B2 and the third refractive layer B3. It is preferable that the plurality of quantum dots may be dispersed into all the first refractive layer B1, the second refractive layer B2 and the third refractive layer B3.

In an example, in the planarization layer PL disposed at the red pixel P_R, a plurality of second quantum dots QD2 may be dispersed for converting white light into red light. In the planarization layer PL disposed at the green pixel P_G, a plurality of first quantum dots QD1 may be dispersed for converting white light into green light. Further, in the planarization layer PL disposed at the blue pixel P_B, a plurality of third quantum dots QD3 may be dispersed for converting white light into blue light.

By the quantum dots allocated at each pixel P, light emitted from the emission layer EL to the downward direction and reflected by the reflective electrode REF to upward direction may be converted into the colored light assigned to each pixel. After that the colored light may pass through the color filter layer CF, so it is possible to implement more accurately filtered colors by the wavelength of the color band assigned to each pixel.

### Fifth Exemplary Embodiment

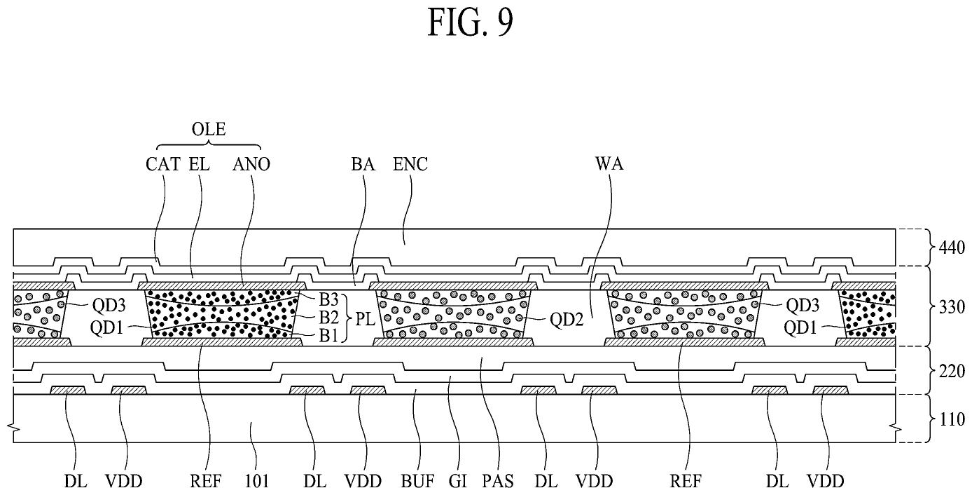

Hereinafter, referring to FIG. 9, a fifth exemplary embodiment of the present disclosure will be explained. FIG. 9 is an example of an enlarged cross-sectional view, cutting along line II-II′ of FIG. 3, for illustrating a structure of three pixels sequentially arrayed in a light emitting display device according to a fifth exemplary embodiment of the present disclosure. The light emitting display device according to the fifth exemplary embodiment shown in FIG. 9 may have a very similar structure with the fourth exemplary embodiment shown in FIG. 8. The explanation for same structure with the fourth exemplary embodiment may be not duplicated or may be briefly given.

In the fifth exemplary embodiment, the color filter layer CF is not disposed on the encapsulation layer 440, dislike the fourth exemplary embodiment. In the case that the color filter layer CF is disposed, it is possible to improve the accuracy or color rendering of each color, but the luminance may be lowered by the color filter layer CF. Therefore, when a display device with brighter luminance is required with the same driving power consumption, it is desirable to use the light emitting display device according to the fifth exemplary embodiment in which the color filter layer CF is removed from the light emitting display device according to the fourth exemplary embodiment.

### Sixth Exemplary Embodiment

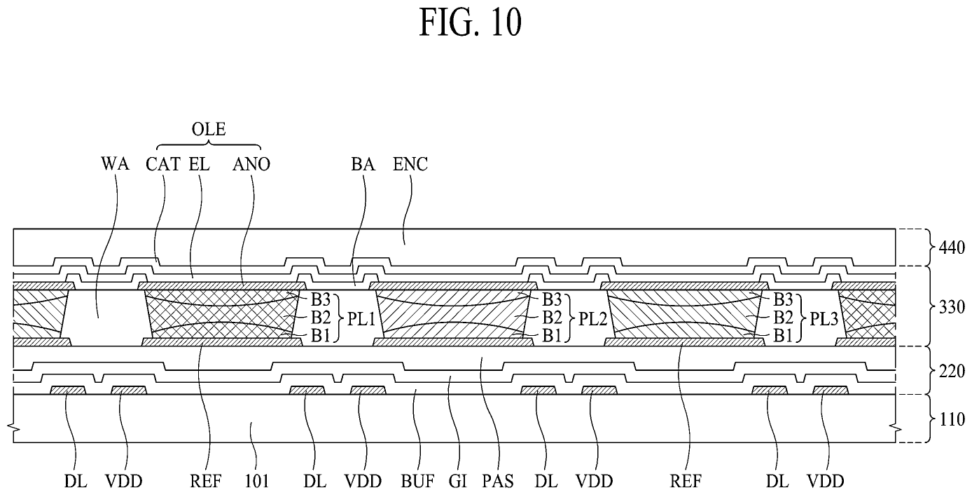

Hereinafter, referring to FIG. 10, a sixth exemplary embodiment of the present disclosure will be explained. FIG. 10 is an example of an enlarged cross-sectional view, cutting along line II-II′ of FIG. 3, for illustrating a structure of three pixels sequentially arrayed in a light emitting display device according to a sixth exemplary embodiment of the present disclosure. The light emitting display device according to the sixth exemplary embodiment shown in FIG. 10 may have a very similar structure with the fifth exemplary embodiment shown in FIG. 9. The explanation for same structure with the fourth exemplary embodiment may be not duplicated or may be briefly given.

In the sixth exemplary embodiment, instead of quantum dots of the fifth exemplary embodiment, pigments or dyes may be included into the planarization layer PL. The pigments or dyes may be dispersed into at least one of the first refractive layer B1, the second refractive layer B2 and the third refractive layer B3. It is preferable that the pigments or dyes may be dispersed into all the first refractive layer B1, the second refractive layer B2 and the third refractive layer B3. However, embodiments of the present disclosure are not limited thereto.

In detail, a red pigment or a red dye may be dispersed in the first planarization layer PL1 disposed at the red pixel P_R. A green pigment or a green dye may be dispersed in the second planarization layer PL2 disposed at the green pixel P_G. Further, a blue pigment or a blue dye may be dispersed in the third planarization layer PL3 disposed at the blue pixel P_B.

In another case, a color filter layer CF may be further disposed on the encapsulation layer 440. When the color filter layer CF is provided, there is an advantage in that the accuracy or color rendering of each color may be improved. However, luminance may be lowered by the color filter layer CF. Therefore, when a display device with brighter luminance is required at the same driving power consumption, it is preferable to use the light emitting display device shown in FIG. 10 without the color filter layer CF.

The light emitting display device according to one or more embodiments of the present disclosure may be applied to mobile apparatuses, video phones, smart watches, watch phones, wearable apparatuses, foldable apparatuses, rollable apparatuses, bendable apparatuses, flexible apparatuses, curved apparatuses, variable apparatuses, sliding apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, home appliances, etc., but embodiments of the present disclosure are not limited thereto.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment may be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the technical idea and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A light emitting display device comprising:
a substrate;
a driving element layer disposed on the substrate;
a reflective electrode disposed on the driving element layer;
a partition wall covering a circumference of the reflective electrode and exposing a middle portion of the reflective electrode;
a planarization layer filling an inside area surrounded by the partition wall, and including a first refractive layer and a second refractive layer;
an anode electrode disposed on the planarization layer;
an emission layer disposed on the anode electrode; and
a cathode electrode disposed on the emission layer.

2. The light emitting display device according to claim 1, wherein an interface between the first refractive layer and the second refractive layer has a curved surface.

3. The light emitting display device according to claim 1, wherein the first refractive layer has a first refractive index, and
wherein the second refractive layer has a second refractive index different from the first refractive index.

4. The light emitting display device according to claim 3, wherein the first refractive index is smaller than the second refractive index.

5. The light emitting display device according to claim 1, wherein a cross-sectional shape of the first refractive layer has a convex lens shape, and
wherein a cross-sectional shape of the second refractive layer has a concave lens shape.

6. The light emitting display device according to claim 1, wherein an upper surface of the planarization layer is disposed on a same level as an upper surface of the partition wall.

7. The light emitting display device according to claim 1, wherein the planarization layer includes a plurality of silica nano particles.

8. The light emitting display device according to claim 1, wherein the planarization layer includes a plurality of quantum dots for implementing specific color.

9. The light emitting display device according to claim 8, further comprising:
an encapsulation layer disposed on the cathode electrode; and
a color filter layer disposed on the encapsulation layer.

10. The light emitting display device according to claim 8, wherein the planarization layer includes a plurality of quantum dots implementing color corresponding to the color filter layer.

11. A light emitting display device, comprising:
a substrate;
a red pixel, a green pixel and a blue pixel;
a driving element layer disposed on the substrate;
a reflective electrode disposed at each of the red pixel, the green pixel and the blue pixel and disposed on the driving element layer;
a partition wall covering circumferences of the reflective electrode and exposing middle portions of the reflective electrode;
a planarization layer including a first refractive layer, a second refractive layer and a third refractive layer disposed within an area surrounded by the partition wall;
an anode electrode disposed at each of the red pixel, the green pixel and the blue pixel and disposed on the planarization layer;
a bank covering circumferences of the anode electrode and exposing middle portions of the anode electrode;
an emission layer disposed on the anode electrode and the bank; and
a cathode electrode disposed on the emission layer.

12. The light emitting display device according to claim 11, wherein a cross sectional shape of the first refractive layer has a convex lens shape in which a middle portion is convexed upward,
wherein a cross sectional shape of the second refractive layer has a concave lens shape in which a middle portion is concaved upward, and
wherein a cross sectional shape of the third refractive layer has a convex lens shape in which a middle portion is convexed downward.

13. The light emitting display device according to claim 11, wherein the first refractive layer, the second refractive layer and the third refractive layer have refractive indices that are different from one another.

14. The light emitting display device according to claim 11, wherein the first refractive layer has a first refractive index that is less than a second refractive index of the second refractive layer,
wherein the second refractive layer has the second refractive index that is less than a third refractive index of the third refractive layer, and
wherein the third refractive layer has the third refractive index that is less than a refractive index of the anode electrode.

15. The light emitting display device according to claim 11, further comprising:
an encapsulation layer disposed on the cathode electrode; and
a color filter layer including a red color filter at the red pixel, a green color filter at the green pixel, and a blue color filter at the blue pixel, wherein the color filter layer is disposed on the encapsulation layer.

16. The light emitting display device according to claim 11, wherein the planarization layer includes a plurality of silica nano particles.

17. The light emitting display device according to claim 11, wherein the planarization layer includes a plurality of first quantum dots at the red pixel, a plurality of second quantum dots at the green pixel, and a plurality of third quantum dots at the blue pixel.

18. The light emitting display device according to claim 11, wherein the planarization layer includes a red pigment at the red pixel, a green pigment at the green pixel, and a blue pigment at the blue pixel.
